(19) United States
(12) Patent Application Publication
(10) Pub. No.: US 2024/0251613 A1
(43) Pub. Date: Jul. 25, 2024

(54) DISPLAY DEVICE AND METHOD OF FABRICATING THE SAME

(71) Applicant: Samsung Display Co., Ltd., Yongin-Si (KR)

(72) Inventors: Guanghai JIN, Yongin-si (KR); Yong Seog KIM, Yongin-si (KR)

(21) Appl. No.: 18/383,049

(22) Filed: Oct. 24, 2023

(30) Foreign Application Priority Data
Jan. 25, 2023 (KR) 10-2023-0009292

(51) Int. Cl. H10K 59/131; H10K 59/12; H10K 59/88

(52) U.S. Cl. CPC H10K 59/131; H10K 59/1201; H10K 59/88; H10K 2102/3026

(57) ABSTRACT

The present disclosure relates to a display device and a method of fabricating the same. According to an embodiment of the disclosure, a display device comprising a plurality of sub-pixels formed in a display area of a display panel, a plurality of gate lines and a plurality of data lines electrically connected to the plurality of sub-pixels, a plurality of fan-out lines formed in a non-display area of the display panel to be electrically connected to the plurality of data lines, a plurality of gate control lines electrically connected to a gate driver formed in the non-display area, and at least one line number identification pattern formed on at least one line among the plurality of gate lines, the plurality of data lines, the plurality of fan-out lines, and the plurality of gate control lines, wherein the line number identification pattern represents a line number for the at least one line.

### CROSS-REFERENCE TO RELATED APPLICATION

This application claims priority from Korean Patent Application No. 10-2023-0009292 filed on Jan. 25, 2023, in the Korean Intellectual Property Office, and all the benefits accruing therefrom under 35 U.S.C. 119, the content of which in its entirety is herein incorporated by reference.

### BACKGROUND

### 1. Field of the Disclosure

The present disclosure relates to a display device and a method of fabricating the same.

### 2. Description of the Related Art

Display devices become increasingly important as multimedia technology evolves. Accordingly, a variety of types of display devices such as organic light-emitting display (OLED) devices and liquid-crystal display (LCD) devices are currently used.

Display devices include a display panel such as an organic light-emitting display panel and a liquid-crystal display panel for displaying images. Among them, a light emitting display panel includes a light emitting element, and light emitting diodes (Light Emitting Diodes, LEDs) among light emitting devices are classified into organic light emitting diodes (OLEDs) using organic materials as fluorescent materials, inorganic light emitting diodes using inorganic materials as fluorescent materials, and the like.

Such a display device may include a display area in which a plurality of pixels displaying images are disposed and a non-display area around the display area. Various lines such as gate lines and data lines for driving pixels may be integrated in the non-display area. In recent years, in order to facilitate confirmation of defects that occur during the manufacturing process and repair proceedings, line numbers for various lines such as gate lines and data lines are identified.

### SUMMARY

Aspects of the present disclosure provide a display device capable of identifying line numbers by forming a line number identification pattern on at least one line such as gate line, data line, and a fan-out line, and the method for manufacturing the same.

Aspects of the present disclosure provide a display device capable of forming a line number identification pattern while maintaining the interval between adjacent lines such as gate lines, data lines, and fan-out lines, and the method for manufacturing the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

The disclosure pertains to a display device including a plurality of sub-pixels formed in a display area of a display panel, a plurality of gate lines and a plurality of data lines electrically connected to the plurality of sub-pixels, a plurality of fan-out lines formed in a non-display area of the display panel to be electrically connected to the plurality of data lines, a plurality of gate control lines electrically connected to a gate driver formed in the non-display area, and at least one line number identification pattern formed on at least one line among the plurality of gate lines, the plurality of data lines, the plurality of fan-out lines, and the plurality of gate control lines, wherein the line number identification pattern represents a line number for the at least one line.

At least one line number identification pattern may be formed on the one line as a wide portion that is wider than the at least one line, wherein there is a group formed of at least one wide portion on the at least one line to represent the line number.

At least one line number identification pattern may comprise a first identification pattern having either a square shape or a rectangular shape.

At least one line number identification pattern may further comprise a second identification pattern having a rectangular shape formed on the line.

There may be a plurality of first identification patterns spaced apart from each other and from the second identification pattern.

A number of the first identification patterns on the at least one line may represent a line number.

The second identification pattern may have a length or shape different from the first identification pattern so that the second identification pattern is recognized as one predetermined number.

At least one line may have a first width, wherein the first and second identification patterns are formed to have a second width greater than the first width, wherein an edge of at least one of the first and second identification patterns extends beyond an edge of the at least one line by a third width, and wherein the third width is smaller than the first width.

At least one line may have a first width, wherein the first and second identification patterns are formed to have a second width that is greater than the first width, wherein an edge of at least one of the first and second identification patterns extends beyond an edge of the at least one line by at least a third width along two sides of the at least one line, and wherein the third width may be smaller than the first width.

The plurality of gate control lines and the at least one line number identification pattern formed on the at least one gate control line among the plurality of gate control lines may be made of the same material on the same layer as a gate electrode through the same patterning process as the gate electrode of a thin film transistor included in a sub-pixel of the display area.

The plurality of fan-out lines and at least one line number identification pattern formed on at least one fan-out line among the plurality of fan-out lines may be made of the same material on the same layer as a gate electrode through the same patterning process as the gate electrode of a thin film transistor included in a sub-pixel of the display area.

The plurality of fan-out lines and at least one line number identification pattern formed on at least one fan-out line among the plurality of fan-out lines may be made of the same material on the same layer as source and drain electrodes through the same patterning process as the source and drain electrodes of a thin-film transistor included in a sub-pixel of the display area.

The plurality of gate control lines and the at least one line number identification pattern formed on at least one gate control line among the plurality of gate control lines may be made of the same material on the same layer as source and drain electrodes through the same patterning process as the source and drain electrodes of a thin-film transistor included in a sub-pixel of the display area.

The disclosure also pertains to a method of manufacturing a display device, the method comprising forming a barrier layer in a display area and a non-display area of a substrate, forming a thin-film transistor on the barrier layer in the display area, forming a plurality of gate lines and a plurality of data lines to be electrically connected to the thin-film transistor, forming a plurality of fan-out lines in the non-display area to be electrically connected to the plurality of data lines, and forming a plurality of gate control lines to be electrically connected to a gate driver formed in the non-display area, wherein, in forming at least one line among the plurality of gate lines, the plurality of data lines, the plurality of fan-out lines and the plurality of gate control lines, at least one line number identification pattern is formed on the at least one line.

The plurality of gate control lines and the at least one line number identification pattern on at least one gate control line among the plurality of gate control lines may be formed by using the same material on the same layer as a gate electrode through the same patterning process as the gate electrode of a thin-film transistor formed in the display area.

The plurality of fan-out lines and the at least one line number identification pattern on at least one fan-out line among the plurality of fan-out lines may be formed by using the same material on the same layer as a gate electrode through the same patterning process as the gate electrode of a thin-film transistor formed in the display area.

The plurality of fan-out lines and the at least one line number identification pattern on at least one fan-out line among the plurality of fan-out lines may be formed by using the same material on the same layer as source and drain electrodes through the same patterning process as the source and drain electrodes of a thin-film transistor formed in the display area.

The plurality of gate control lines and the at least one line number identification pattern on at least one gate control line among the plurality of gate control lines may be formed by using the same material on the same layer as source and drain electrodes through the same patterning process as the source and drain electrodes of a thin film transistor formed in the display area.

The at least one line number identification pattern may comprise a first identification pattern formed in a square shape or formed in a rectangular shape, and a second identification pattern formed in a rectangular shape with sides that extend in the same direction as the at least one line being longer than the sides that extend perpendicularly to the at least one line.

A number of the first identification patterns on the at least one line represents a line number, and wherein the second identification pattern may have a length or shape different from the first identification pattern to represent a predetermined number.

According to a display device and a method of manufacturing the display device according to an embodiment, the line number identification pattern can be formed while maintaining the interval between adjacent lines, such as gate lines, data lines, and fan-out lines. In addition, the line numbers may be identified more easily.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view showing the configuration of a display device according to an embodiment of the present disclosure;

FIG. 2 is a cross-sectional view showing a side of the display device of FIG. 1 in detail;

FIG. 3 is a view showing an example of a layout of a display panel according to an embodiment of the present disclosure;

FIG. 4 is an enlarged view of an example more specifically showing region A1 of FIG. 3;

FIG. 5 is an enlarged view of another example more specifically showing region A1 of FIG. 3;

FIG. 6 is an enlarged view more specifically showing eighth and ninth fan-out lines of FIG. 5;

FIG. 7 is a cross-sectional view showing cross-sectional structures of any one of sub-pixels and a first gate control line formed in the display panel;

FIG. 8 is a cross-sectional view showing cross-sectional structures of any one of sub-pixels and a first fan-out line formed in the display panel;

FIGS. 9 and 10 are perspective views of a display device according to another embodiment of the present disclosure;

FIGS. 11 and 12 are perspective views of a display device 10 according to an embodiment of the present disclosure.

### DETAILED DESCRIPTION OF THE EMBODIMENTS

The present disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

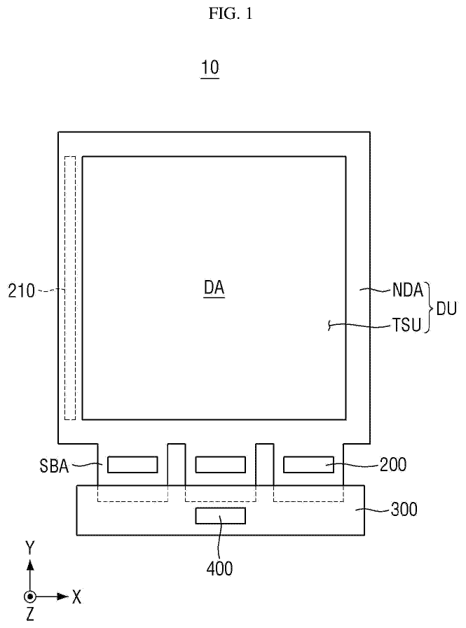

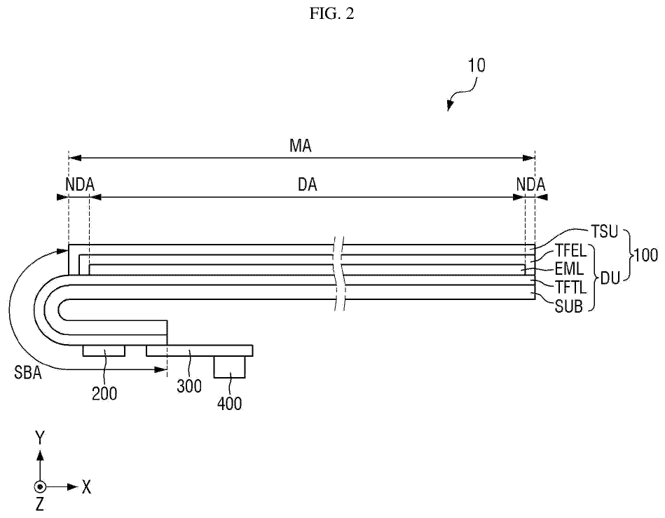

FIG. 1 is a plan view showing the configuration of a display device according to an embodiment of the present disclosure. FIG. 2 is a cross-sectional view showing a side of the display device of FIG. 1 in detail.

Referring to FIGS. 1 and 2, a display device 10 according to an embodiment may be sorted into a variety of devices depending on the way images are displayed. For example, the display device 10 may be classified into and implemented as an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a liquid-crystal display device (LCD), an electrophoretic display device (EPD), etc. In the following description, an organic light-emitting display device (OLED) will be described as an example of the display device. The organic light-emitting display device (OLED) will be simply referred to as the display device 10 unless it is necessary to distinguish between them. It is, however, to be understood that the embodiments of the present disclosure are not limited to the organic light-emitting display device (OLED), and one of the above-listed display devices or any other display device well known in the art may be employed as the display device 10 without departing from the scope of the present disclosure.

The display device 10 according to an embodiment of the present disclosure may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). In some cases, the display device 10 may be applied to wearable devices such as a smart watch, a watch phone, a glasses-type display, and a head-mounted display (HMD) device. The display device 10 according to the embodiment may be used as a center information display (CID) disposed at the instrument cluster, the center fascia or the dashboard of a vehicle, and may also be used as a mirror display on a vehicle.

According to the embodiment of the present disclosure, the display device 10 may have one of a rectangular shape, a square shape, a circular shape, and an elliptical shape in plan view. For example, when the display device 10 is used in a wearable device or a vehicle, it may have a rectangular shape in which the longer sides are located in the horizontal direction. It should be understood, however, that the present disclosure is not limited thereto. The display device 10 may have a rectangular shape in which the longer sides are located in the vertical direction. Alternatively, the display device 10 may be installed rotatably so that the longer sides can be adjusted to extend in the horizontal or vertical direction.

As shown in FIGS. 1 and 2, the display device 10 may include a touch sensing module. The touch sensing module includes a touch sensing unit TSU disposed on the front surface of a display panel 100, and a touch driver circuit 400 for generating touch position coordinate data of the touch sensing unit TSU.

For example, the display panel 100 of the display device 10 may include a display unit DU displaying images, and a touch sensing unit TSU is disposed on the display panel 100 to sense a touch by a touch input device such as a part of a human body, e.g., a finger and an electronic pen. The display unit DU of the display panel 100 may include a plurality of pixels and may display images through the plurality of pixels. Each pixel may include red, green and blue sub-pixels, or red, green, blue and white sub-pixels.

The touch sensing unit TSU may be mounted on the front surface of the display panel 100 or formed integrally with the display panel 100. The touch sensing unit TSU may include a plurality of touch electrodes to sense a user's touch by capacitive sensing using the touch electrodes. The elements and structural features of the touch sensing unit TSU will be described in more detail later with reference to the accompanying drawings.

A display driver circuit 200 may output signals and voltages for driving pixels in the display unit DU, i.e., each of the sub-pixels. The display driver circuit 200 may supply data voltages to data lines connected to the sub-pixels. The display driver circuit 200 may supply a power voltage to the power line and may supply gate control signals to a gate driver 210. It should be noted that the display driver circuit 200 may be divided into a display driver circuit 200 performing a timing control function and a data driver supplying data voltages to data lines. In such case, the display driver circuit 200 may supply a timing control signal to the gate driver 210 and the data driver to control driving timings of the gate driver 210 and the data driver.

The display driver circuit 200 may be implemented as an integrated circuit (IC) and may be attached on the display panel 100 by a chip-on-glass (COG) technique, a chip-on-plastic (COP) technique, or ultrasonic bonding. For example, the display driver circuit 200 may be disposed in the subsidiary area SBA and may overlap with the main area MA in the thickness direction (z-axis direction) as the subsidiary area SBA is bent. For another example, the display driver circuit 200 may be mounted on the circuit board 300.

The touch driver circuit 400 may be electrically and physically connected to the touch sensing unit TSU. The touch driver circuit 400 may supply touch driving signals to a plurality of touch electrodes arranged in a matrix in the touch sensing unit TSU and may sense a change in the capacitance between the plurality of touch electrodes. The touch driver circuit 400 may determine whether a user's touch is input and may produce the touch coordinate data based on the amount of the change in the capacitance between the touch electrodes.

The display driver circuit 200 may operate as a main processor or may be formed integrally with the main processor. Accordingly, the display driver circuit 200 may control overall functions of the display device 10. For example, the display driver circuit 200 may receive touch data from the touch driver circuit 400 to determine the user's touch coordinates, and then may generate digital video data based on the touch coordinates. In addition, the display driver circuit 200 may run an application indicated by an icon displayed on the user's touch coordinates. For another example, the display driver circuit 200 may receive coordinate data from an electronic pen to determine the touch coordinates of the electronic pen, and then may generate digital video data according to the touch coordinates or may run an application indicated by an icon displayed at the touch coordinates of the electronic pen.

Referring to FIG. 2, the display panel 100 may be divided into a main area MA and a subsidiary area SBA. The main area MA may include a display area DA where the sub-pixels for displaying images are disposed, and a non-display area NDA located around the display area DA. In the display area DA, light may be emitted from an emission area or an opening area of each sub-pixel to display an image. To this end, each of the sub-pixels in the display area DA may include a pixel circuit including switching elements, a pixel-defining layer that defines the emission area or the opening area, and a self-light-emitting element.

The non-display area NDA may be the peripheral area, i.e., the outer area of the display area DA. The non-display area NDA may be defined as the edge area of the main area MA of the display panel 100. The non-display area NDA may include a gate driver (not shown) that applies gate signals to gate lines, and fan-out lines (not shown) that connect the display driver circuit 200 with the display area DA.

The subsidiary area SBA may extend from one side of the main area MA. The subsidiary area SBA may include a flexible material that can be bent, folded, or rolled. For example, when the subsidiary area SBA is bent, the subsidiary area SBA may overlap the main area MA in the thickness direction (z-axis direction). The subsidiary area SBA may include pads connected to the display driver circuit 200 and the circuit board 300. Optionally, the subsidiary area SBA may be eliminated, and the display driver circuit 200 and the pads may be disposed in the non-display area NDA.

The circuit board 300 may be attached on the pads of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

Incidentally, the substrate SUB of the display panel 100 shown in FIG. 2 may be a base substrate or a base member. The substrate SUB may be of a flat type. Alternatively, the substrate SUB may be a flexible substrate that can be bent, folded, or rolled. For example, the substrate SUB may include, but is not limited to, a glass material or a metal material. As another example, the substrate SUB may include a polymer resin such as polyimide PI.

The thin-film transistor layer TFTL may be disposed on the substrate SUB. The thin-film transistor layer TFTL may include a plurality of thin-film transistors forming pixel circuits of the sub-pixels SP. The thin-film transistor layer TFTL may include gate lines, data lines, power lines, gate control lines, fan-out lines for connecting the display driver circuit 200 with the data lines, lead lines for connecting the display driver circuit 200 with the pads, etc. When the gate driver 210 is formed on one side of the non-display area NDA of the display panel 100, the gate driver 210 may include thin-film transistors.

The thin-film transistor layer TFTL may be disposed in the display area DA, the non-display area NDA and the subsidiary area SBA. The thin-film transistors in each of the pixels, the gate lines, the data lines and the power lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

An emission material layer EML may be disposed on the thin-film transistor layer TFTL. The emission material layer EML may include a plurality of light-emitting elements, each of which includes a first electrode, an emissive layer and a second electrode stacked on one another to emit light, and a pixel-defining layer for defining each of the sub-pixels. Light-emitting elements of the emission material layer EML may be disposed in the display area DA.

An encapsulation layer TFEL may cover the upper and side surfaces of the emission material layer EML, and can protect the emission material layer EML. The encapsulation layer TFEL may include at least one inorganic layer and at least one organic layer for encapsulating the emission material layer EML.

The touch sensing unit TSU may be disposed on the encapsulation layer TFEL of the display panel 100. The touch sensing unit TSU may include a plurality of touch electrodes for sensing a user's touch by capacitive sensing, and touch driving lines connecting the plurality of touch electrodes with the touch driver circuit 400. The first touch electrodes of the touch sensing unit TSU may be arranged in a matrix to sense a user's touch by self-capacitance sensing or mutual capacitance sensing.

The touch sensing unit TSU may not be formed integrally with the display panel 100 but may be disposed on a separate substrate or film disposed on the display unit DU of the display panel 100. In such case, the substrate of the film supporting the touch sensing unit TSU may be a base member encapsulating the display unit DU.

The plurality of touch electrodes including the touch sensing unit TSU may be disposed in a touch sensor area overlapping the display area DA. The touch lines of the touch sensing unit TSU may be disposed in a touch peripheral area overlapping the non-display area NDA.

The touch driver circuit 400 may be mounted on a separate circuit board 300. The touch driver circuit 400 may be implemented as an integrated circuit (IC). The touch driver circuit 400 supplies the touch driving signals to the touch electrodes of the touch sensing unit TSU, and measures the amount of a change in mutual capacitance of each of a plurality of touch nodes formed by the touch electrodes.

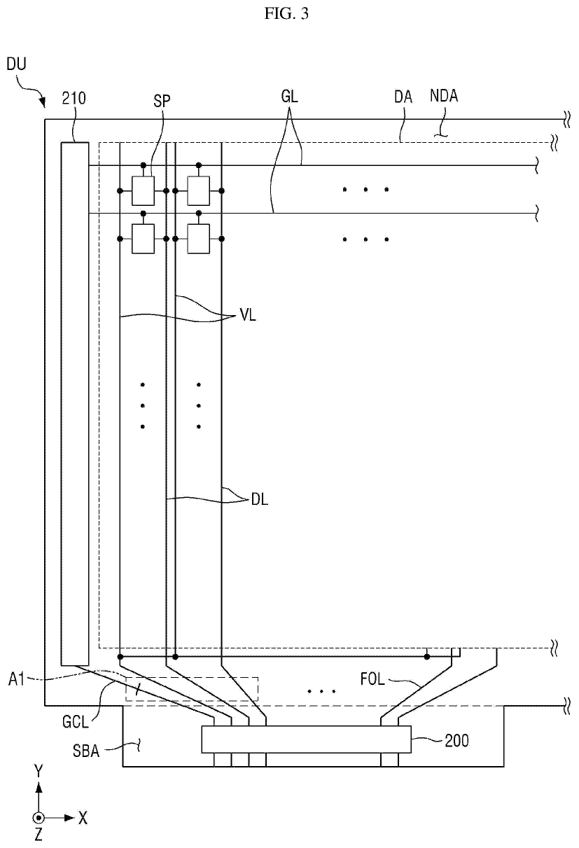

FIG. 3 is a view showing an example of a layout of a display panel according to an embodiment of the present disclosure. Specifically, FIG. 3 is a layout view showing the display area DA and the non-display area NDA of the display unit DU before the touch sensing unit TSU is formed.

The display area DA displays images therein and may be defined as a central area of the display panel 100. The display area DA may include a plurality of sub-pixels SP, a plurality of gate lines GL, a plurality of data lines DL, a plurality of power lines VL, etc. Each of the plurality of sub-pixels SP may be defined as the minimum unit that outputs light.

The plurality of gate lines GL may supply the gate signals received from the gate driver 210 to the plurality of sub-pixels SP. The plurality of gate lines GL may be extended in the X-axis direction and may be spaced apart from one another in the Y-axis direction crossing the x-axis direction.

The plurality of data lines DL may supply the data voltages applied from the display driver circuit 200 to the plurality of sub-pixels SP. The plurality of data lines DL may extend in the y-axis direction and may be spaced apart from one another in the x-axis direction.

The plurality of power lines VL may supply the power voltage applied from the display driver circuit 200 to the plurality of sub-pixels SP. The supply voltage may be at least one of a driving voltage, an initialization voltage, and a reference voltage. The plurality of power lines VL may be extended in the Y-axis direction and may be spaced apart from one another in the X-axis direction.

The non-display area NDA may surround the display area DA. The non-display area NDA may include the gate driver 210, fan-out lines FOL, and gate control lines GCL. The gate driver 210 may generate a plurality of gate signals based on the gate control signal inputted through gate control lines GCL, and may sequentially supply the plurality of gate signals to the plurality of gate lines GL in a predetermined order.

The fan-out lines FOL may extend from the display driver circuit 200 to the display area DA. The fan-out lines FOL may supply the data voltage received from the display driver circuit 200 to the plurality of data lines DL.

The gate control line GCL may extend from the display driver circuit 200 to the gate driver 210. The gate control line GCL may supply the gate control signal received from the display driver circuit 200 to the gate driver 210.

The display driver circuit 200 may output signals and voltages for driving the display panel 100 to the fan-out lines FOL. The display driver circuit 200 may supply data voltages to the data lines DL through the fan-out lines FOL. The data voltages may be applied to the plurality of sub-pixels SP, so that the luminance of the plurality of sub-pixels SP may be determined. The display driver circuit 200 may supply a gate control signal to the gate driver 210 through the gate control line GCL.

At least on one of the gate lines GL, data lines DL, and power lines VL formed in the display area DA, a line number identification pattern may be formed to check for defects that occur during the manufacturing process and facilitating repair. Also, the line number identification pattern may be formed on at least one of the fan-out lines FOL and the gate control lines GCL formed in the non-display area NDA. Line number identification patterns are detected by a microscope, an image sensor, a camera, a light reflection pattern detection module, and the like, so that process personnel can identify the line numbers of the lines on which the line number identification patterns are formed.

Hereinafter, an example in which line number identification patterns are formed on the fan-out lines FOL and gate control lines GCL formed in the non-display area NDA will be described. Lines described in the embodiment are not limited to fan-out lines FOL and gate control lines GCL, and may be applied to lines such as gate lines GL, data lines DL, lead lines, and power lines VL. Here, the fan-out lines FOL and the data lines DL may be integrally formed, but are not limited thereto. Meanwhile, the fan-out lines FOL and the data lines DL may be formed on different layers and electrically connected to each other by a contact hole or the like. The gate control lines GCL and gate lines GL may also be formed on different layers.

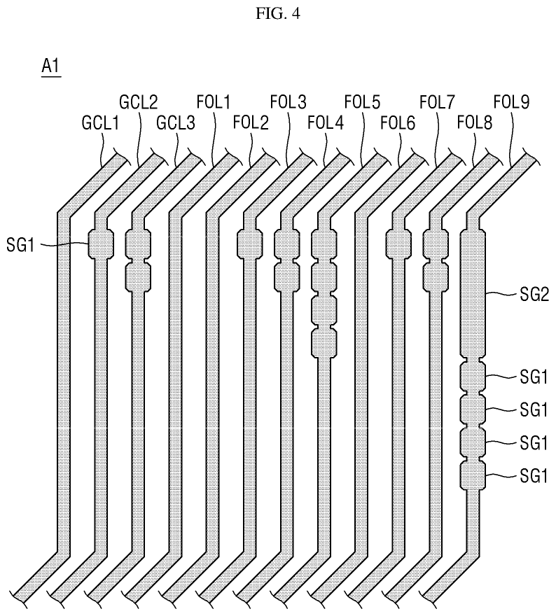

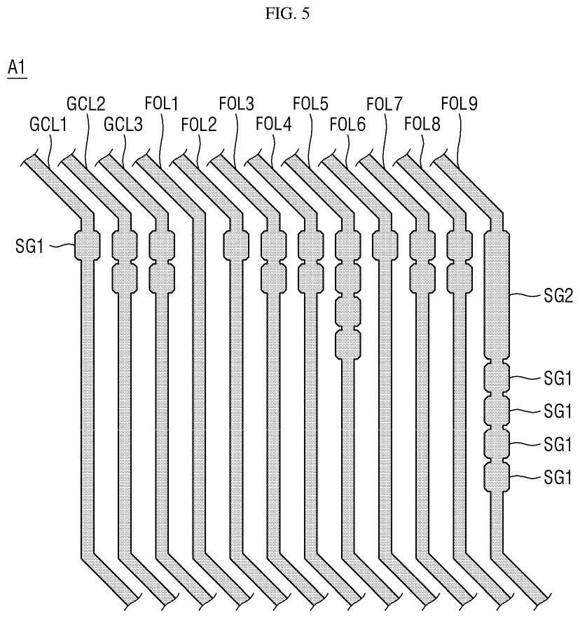

FIG. 4 is an enlarged view of an example more specifically showing region A1 of FIG. 3. In addition, FIG. 5 is an enlarged view of another example more specifically showing region A1 of FIG. 3.

Referring to FIGS. 4 and 5, at least one of line number identification patterns SG1 and SG2 may be formed selectively on lines of the display device 10 according to one embodiment, for example, the gate control lines GCL and the fan-out lines FOL.

At least one of line number identification patterns SG1 and SG2 may be formed on each gate control line GCL and fan-out lines FOL in its thickness or width direction to form a group identified by line numbers for each gate control line GCL and fan-out lines FOL. In other words, portions of the gate control lines GCL and fan-out lines FOL having a relatively wide width by changing the line width may become the line number identification patterns SG1 and SG2.

Each of the lines, for example, gate control lines GCL and fan-out lines FOL may extend in a length direction (e.g., Y-axis direction) and may be spaced apart from each other in a width (or thickness) direction (e.g., X-axis direction). In some embodiments, the gate control lines GCL and fan-out lines FOL may have a width of approximately 2 μm to 3 μm, but are not limited thereto.

At least one of line number identification patterns SG1 and SG2 formed on the gate control lines GCL and fan-out lines FOL is formed of one group for each gate control line GCL and fan-out lines FOL to form each identification number.

The at least one of line number identification patterns SG1 and SG2 includes the first identification pattern SG1 of a square shape in which a first side in the X-axis direction and a second side in the Y-axis direction have the same length or width on a plane, and the second identification pattern SG2 of a rectangular shape having longer length or width of the second side than the length or width of the first side. In addition, the at least one of the line number identification pattern SG1 and SG2 may also include third identification pattern of a rectangular shape having a longer length or width of the first side in the X-axis direction than the length or width of the second side in the Y-axis direction on a plane.

The number of first identification patterns SG1 constituting one group for each gate control line GCL and each fan-out line FOL may be the same as the preset line number or identification number. Here, the first identification patterns SG1 formed in the same number as the line numbers or identification numbers are spaced apart from other adjacent first identification patterns SG1 and second identification patterns SG2.

When the line number or identification number for any one of the gate control line GCL and the fan-out lines FOL is 0, the first identification pattern SG1 may not be formed on the gate control line GCL and the fan-out lines FOL.

Line numbers of the first gate control line GCL1 and the first and sixth fan-out lines FOL1 and FOL6 shown in FIG. 4 may be 0. The first identification pattern SG1 and the second identification pattern SG2 are not formed on a first gate control line GCL1 and the first, second, and sixth fan-out lines FOL1, FOL2, and FOL6 shown in FIG. 4. As described above, the line number of at least one gate control line GCL1 and fan-out lines FOL1, FOL2, and FOL6 is zero because there is neither the first identification pattern SG1 nor the second identification pattern SG2.

On the other hand, when the line number in respect to each of the gate control line GCL and the fan-out lines FOL is 1, one first identification pattern SG1 is formed. For example, each of the second gate control line GCL2 and the third and seventh fan-out lines FOL3 and FOL7 shown in FIG. 4 is identified with the line number 1 based on the presence of one first identification pattern SG1 on each of those lines.

When the line number for each of the gate control line GCL and the fan-out lines FOL is 2, two first identification patterns SG1 are formed. In the example of FIG. 4, each of the third gate control line GCL3 and the fourth and eighth fan-out lines FOL4 and FOL8 shown in FIG. 4 is identified with the line number is 2 based on there being two first identification patterns SG1 on each line.

Also, when the line number for each of the gate control line GCL and the fan-out lines FOL is 4, four first identification patterns SG1 may be formed. In the examples of FIG. 4 and FIG. 5, the fifth fan-out line FOL5 is identified with the line number is 4 based on the presence of four first identification patterns SG1 on the line.

Each of the first identification pattern SG1 or the second identification pattern SG2 is illustrated to have a rectangular or a square shape in FIGS. 4 and 5, but these are example embodiments and the shapes of the identification patterns SG1, SG2 are not limited to what is depicted. For example, at least one identification pattern of the first identification pattern SG1 and the second identification pattern SG2 may be formed in the shape of a triangle, a rhombus, a circle, an ellipse, a semicircle, or a pentagonal or higher polygon.

The second identification pattern SG2 is formed in a preset length, width, or shape different from the first identification pattern SG1 so that it is recognized as a one preset number. In one embodiment, there may be only one second identification pattern SG2 in a predefined group of gate control lines GCL and fan out lines FOL. Each of FIG. 4 and FIG. 5, for example, depict one group of gate control lines GCL and fan out lines FOL with a single second identification pattern SG2.

In one embodiment, the length of the second identification pattern SG2 in the Y-axis direction may be formed to be longer than the length of the first identification pattern SG1 in the Y-axis direction, and the width or thickness of the second identification pattern SG2 in the X-axis direction may be formed to have the same width or thickness as the first identification pattern SG1. The length of the second identification pattern SG2 in the Y-axis direction may be about 4 or 5 times longer than the length of the first identification pattern SG1 in the Y-axis direction.

Like a ninth fan-out line FOL9 shown in FIGS. 4 and 5, when the length of the second identification pattern SG2 in the Y-axis direction is longer than the length of each of the first identification patterns SG1 in the Y-axis direction, the corresponding second identification pattern SG2 may be recognized as the preset number 5. Accordingly, the ninth fan-out line FOL9 may include the number 4 based on there being four first identification patterns SG1 and the number 5 based on the presence of the second identification pattern SG2. Accordingly, the line number of the ninth fan-out line FOL9 may be recognized as 9, which is a sum 4+5.

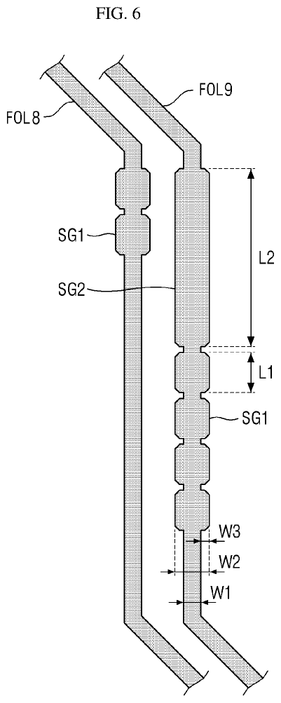

FIG. 6 is an enlarged view more specifically showing eighth and ninth fan-out lines of FIG. 5.

Referring to FIG. 6, in an embodiment, the gate control lines GCL and the fan-out lines FOL may each be formed to have a preset first width W1. Here, the preset first width W1 may be approximately set to any one of 2 μm to 3 μm.

Also referring to FIG. 6, each of the first and second identification patterns SG1 and SG2 may be formed to have a second width W2 which protrudes beyond the boundary of the first width W1 by at least a third width W3 in both the gate control lines GCL and fan-out lines FOL.

The third width W3, which is the distance between an edge of either the gate control lines GCL or the fan-out lines FOL and an edge of the identification pattern SG1/2, may be smaller or narrower than the first width W1 that is the width of the gate control lines GCL and the fan-out lines FOL. The third width W3 protruding from the gate control lines GCL and fan-out lines FOL may be set to a distance between 0.2 μm and 1.4 μm, inclusive.

More specifically, the first and second identification patterns SG1 and SG2 may be formed to have the second width W2 protruding beyond the outer edge of the gate control lines GCL or the fan-out lines FOL by at least the third width W3 on both sides of the first width W1 of the gate control lines GCL and the fan-out lines FOL. Accordingly, the second width W2 of the first and second identification patterns SG1 and SG2 may be set to approximately one of 2.4 μm to 5.8 μm.

Each of the first identification patterns SG1 may be formed in a square shape in which a first side in the X-axis direction and a second side in the Y-axis direction have the same length or width on a plane, or a rectangular shape in which the dimension of a first side in the X-axis direction is longer than a length L1 in the Y-axis direction on a plane. Such first identification pattern SG1 is disposed to be spaced apart from other adjacent first identification patterns SG1 and second identification patterns SG2 that are formed on the same line.

On the other hand, the second identification pattern SG2 is formed with a preset length and width so as to be recognized as a preset number. For example, a length L2 of the second identification pattern SG2 in the Y-axis direction may be formed to be longer than the length L1 of the first identification pattern SG1 in the Y-axis direction, and a width W2 or thickness of the second identification pattern SG2 in the X-axis direction may be formed to be the same as a width W2 or thickness of the first identification pattern SG1. The length L2 of the second identification pattern SG2 in the Y-axis direction may be formed to be about 4 or 5 times longer than the length L1 of the first identification pattern SG1 in the Y-axis direction.

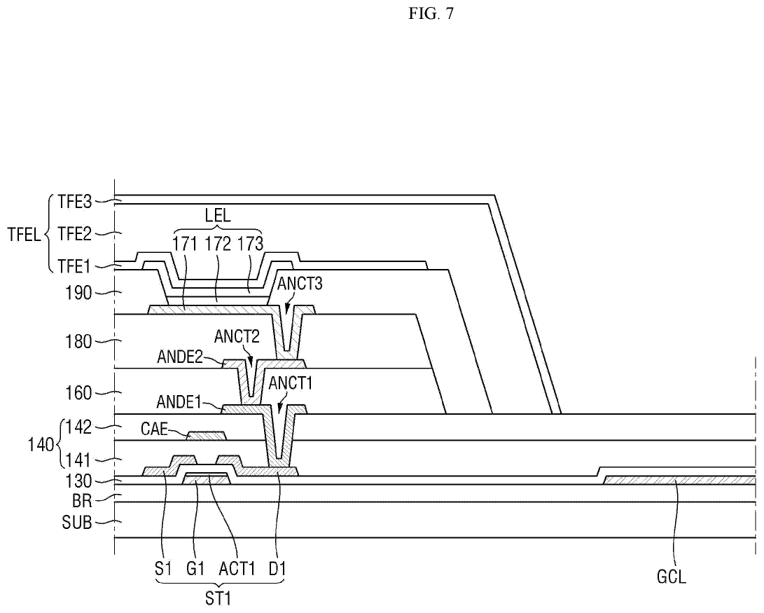

FIG. 7 is a cross-sectional view showing cross-sectional structures of any one of sub-pixels and a first gate control line formed in the display panel.

Referring to FIG. 7, the substrate SUB may be made of an insulating material such as polymer resin. For example, the substrate SUB may be made of polyimide or glass. The substrate SUB may be a flexible substrate that can be bent, folded, or rolled. Alternately, the substrate SUB may be a flat type substrate.

A barrier layer BR may be first formed on the substrate SUB. The barrier layer BR is a layer for protecting transistors of the thin-film transistor layer TFTL and light emitting layers 172 of the emission material layer EML from moisture introduced through the substrate SUB which is vulnerable to moisture penetration. The barrier layer BR may be composed of a plurality of inorganic layers stacked alternately. For example, the barrier layer BR may be a multilayer in which one or more inorganic layers selected from a silicon nitride layer, a silicon oxynitride layer, a silicon oxide layer, a titanium oxide layer, and an aluminum oxide.

Thin-film transistors ST1 are disposed on the barrier layer BR of the display area DA. On the other hand, the gate control lines GCL may be formed on the barrier layer BR of the non-display area NDA.

Specifically, a gate electrode G1 of the thin-film transistor ST1 is formed on the barrier layer BR of the display area DA, and the gate control lines GCL may be formed on the barrier layer BR of the non-display area NDA in the same material as the gate electrode G1 and using the same patterning process as that of the gate electrode G1.

As another example, although not shown in the cross-sectional view of FIG. 7, fan-out lines may be formed on the barrier layer BR of the non-display area NDA in the same material as the gate electrode G1 and using the same patterning process as that of the gate electrode G1. In other words, the gate control lines GCL and the fan-out lines FOL may be formed on the barrier layer BR of the non-display area NDA through the same patterning process as that of the gate electrode G1.

The gate electrode G1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

When the gate electrode G1 is formed of multiple layers including first and second gate electrodes, an active layer ACT1 may be formed on a first gate electrode by doping at least one of polycrystalline silicon, single crystal silicon, low-temperature polycrystalline silicon, amorphous silicon, and an oxide semiconductor. And a second gate electrode may be patterned and disposed on the active layer ACT1. In this case, gate control line GCL may be formed on the barrier layer BR of the non-display area NDA in the same material as the second gate electrode and using the same patterning process as that of the second gate electrode.

A gate insulating layer 130 is formed on the entire surface of the barrier layer BR including the gate electrode G1 of the thin-film transistor ST1 and the gate control line GCL. The gate insulating layer 130 may be formed as an inorganic layer, for example, a silicon nitride layer, a silicon oxynitride layer, a silicon oxide layer, a titanium oxide layer, or an aluminum oxide layer.

A source electrode S1 and a drain electrode D1 constituting the thin-film transistor ST1 may be disposed on the gate insulating layer 130 of the display area DA.

The source electrode S1 and the drain electrode D1 may partially overlap the gate electrode G1. Each of the source electrode S1 and the drain electrode D1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A first interlayer insulating layer 141 may be disposed on the gate insulating layer 130 including the source electrode S1 and the drain electrode D1. The first interlayer insulating layer 141 may be formed as an inorganic layer such as a silicon nitride layer, a silicon oxynitride layer, a silicon oxide layer, a titanium oxide layer, or an aluminum oxide layer. The first interlayer insulating layer 141 may be composed of a plurality of inorganic layers.

Capacitor electrodes CAE may be disposed on the first interlayer insulating layer 141. The capacitor electrodes CAE may overlap the gate electrodes G1 of the thin-film transistor ST1 in the third direction (Z-axis direction). Since the first interlayer insulating layer 141 has a predetermined dielectric constant, capacitors may be formed by the capacitor electrodes CAE, the gate electrode G1, and the first interlayer insulating layer 141 disposed between the capacitor electrodes CAE and the gate electrode G1. The capacitor electrode CAE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A second interlayer insulating layer 142 may be disposed on the capacitor electrodes CAE. The second interlayer insulating layer 142 may be formed as an inorganic layer such as a silicon nitride layer, a silicon oxynitride layer, a silicon oxide layer, a titanium oxide layer, or an aluminum oxide layer. The second interlayer insulating layer 142 may be formed as a plurality of inorganic layers.

First anode connection electrodes ANDE1 may be disposed on the second interlayer insulating layer 142. The first anode connection electrode ANDE1 may be connected to the drain electrode D1 of the thin-film transistor ST1 through a first connection contact hole ANCT1 penetrating through the gate insulating layer 130, the first interlayer insulating layer 141, and the second interlayer insulating layer 142. The first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A first planarization layer 160 for planarizing a step due to the thin-film transistor ST1 may be disposed on the first anode connection electrodes ANDE1. The first planarization layer 160 may be formed as an organic layer made of an acrylic resin, an epoxy resin, a phenolic resin, a polyamide resin, a polyimide resin, or the like.

Second anode connection electrodes ANDE2 may be disposed on the first planarization layer 160. The second anode connection electrode ANDE2 may be connected to the first anode connection electrode ANDE1 through a second connection contact hole ANCT2 penetrating through the first planarization layer 160. The second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. May be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A second planarization layer 180 may be disposed on the second anode connection electrodes ANDE2. The second planarization layer 180 may be formed as an organic layer made of an acrylic resin, an epoxy resin, a phenolic resin, a polyamide resin, a polyimide resin, or the like.

The light emitting elements LEL and a bank 190 may be formed on a second planarization layer 180. Each of the light emitting elements LEL may include a pixel electrode 171, light emitting layers 172, and a common electrode 173.

The pixel electrode 171 may be disposed on the second planarization layer 180. The pixel electrode 171 may be connected to the second anode connection electrode ANDE2 through a third connection contact hole ANCT3 penetrating through the second planarization layer 180.

In a top emission structure in which light is emitted toward the common electrode 173 based on the light emitting layer 172, the pixel electrode 171 may be formed of a metal material having high reflectivity, such as a stacked structure (Ti/Al/Ti) of aluminum and titanium, a stacked structure (ITO/AI/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the pixel electrodes 171 on the second planarization layer 180, in order to define each of the light emitting areas. The bank 190 may be disposed to cover an edge of the pixel electrode 171. The bank 190 may be formed as an organic layer made of an acrylic resin, an epoxy resin, a phenolic resin, a polyamide resin, a polyimide resin, or the like. Here, each emission area may be an area in which the pixel electrode 171, the light emitting layer 172, and the common electrode 173 are sequentially stacked so that holes from the pixel electrode 171 and electrons from the common electrode 173 are combined to emit light.

The common electrode 173 may be disposed on the light emitting layer 172. The common electrode 173 may cover the light emitting layer 172. The common electrode 173 may be a common layer formed commonly to a first light-emitting area, a second light-emitting area, and a third light-emitting area. A capping layer may be formed on the common electrode 173.

In the top emission structure, the common electrode 173 may be made of a transparent conductive material (TCO) capable of transmitting light, such as indium tin oxide (ITO) or indium zinc oxide (IZO), or a semi-transmissive conductive material such as magnesium (Mg), silver (Ag) or an alloy of Mg and Ag. When the common electrode 173 is made of a semi-transmissive conductive material, light output efficiency may be increased by a microcavity.

The encapsulation layer TFEL may be disposed on the common electrodes 173. The encapsulation layer TFEL includes at least one inorganic layer to prevent oxygen or moisture from permeating into the emission material layer EML. In addition, the encapsulation layer TFEL includes at least one organic layer to protect the emission material layer EML from foreign substances such as dust. For example, the encapsulation layer TFEL includes a first encapsulating inorganic layer TFE1, an encapsulating organic layer TFE2, and a second encapsulating inorganic layer TFE3.

The first encapsulating inorganic layer TFE1 may be disposed on the common electrodes 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

After this, the touch sensing unit TSU illustrated in FIG. 2 may be disposed on the encapsulation layer TFEL.

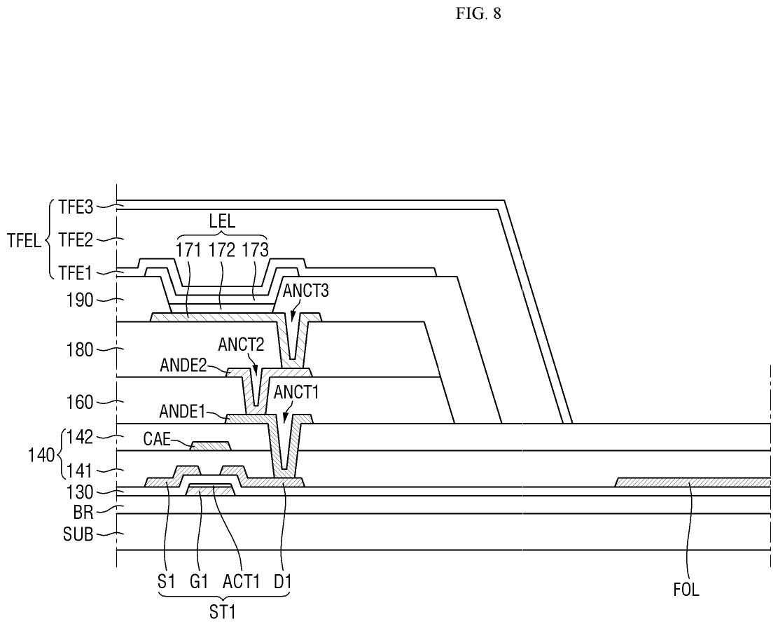

FIG. 8 is a cross-sectional view showing cross-sectional structures of any one of sub-pixels and a first fan-out line formed in the display panel.

Referring to FIG. 8, thin film transistors ST1 are disposed on the barrier layer BR of the substrate SUB.

The gate electrode G1 of the thin film transistor ST1 is formed on the barrier layer BR of the display area DA. The gate electrode G1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

When the gate electrode G1 is formed of multiple layers including first and second gate electrodes, the active layer ACT1 may be formed on a first gate electrode by doping at least one of polycrystalline silicon, single crystal silicon, low-temperature polycrystalline silicon, amorphous silicon, and an oxide semiconductor. The second gate electrode may be patterned and disposed on the active layer ACT1.

The gate insulating layer 130 is formed on the entire surface of the barrier layer BR including the gate electrode G1 of the thin-film transistor ST1 and the gate control lines GCL. The gate insulating layer 130 may be formed as an inorganic film, for example, a silicon nitride layer, a silicon oxynitride layer, a silicon oxide layer, a titanium oxide layer, or an aluminum oxide layer.

The source electrode S1 and the drain electrode D1 constituting the thin-film transistor ST1 may be disposed on the gate insulating layer 130 of the display area DA. At this time, the fan-out lines FOL may be formed on the gate insulating layer 130 of the non-display area NDA in the same materials as the source electrode S1 and the drain electrode D1 through the same patterning process as those of the source electrode S1 and the drain electrode D1.

As another example, although not shown in the cross-sectional view of FIG. 8, the gate control lines GCL may be formed on the gate insulating layer 130 of the non-display area NDA in the same material as the source electrode S1 and the drain electrode D1 through same patterning process as those of the source electrode S1 and the drain electrode D1. In other words, on the gate insulating layer 130 of the non-display area NDA, the fan-out lines FOL and the gate control line GCL may be simultaneously formed through the same patterning process as those of the source electrode S1 and the drain electrode D1.

The source electrode S1 and the drain electrode D1 may partially overlap the gate electrode G1. Each of the source electrode S1 and the drain electrode D1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating layer 141 may be disposed on the gate insulating layer 130 including the source electrode S1 and the drain electrode D1. The first interlayer insulating layer 141 may be made of an inorganic layer, for example, a silicon nitride layer, a silicon oxynitride layer, a silicon oxide layer, a titanium oxide layer, or an aluminum oxide layer. The first interlayer insulating layer 141 may be composed of a plurality of inorganic layers.

Capacitor electrodes CAE may be disposed on the first interlayer insulating layer 141.

Hereinafter, the description of the method for manufacturing the sub-pixel shown in FIG. 8 will be substituted with the detailed description made with reference to FIG. 7. In addition, the structural characteristics of the first and second identification patterns SG1 and SG2 formed by being patterned on the fan-out lines FOL and the gate control lines GCL will be substituted with the detailed description made with reference to FIGS. 4 to 6 described above.

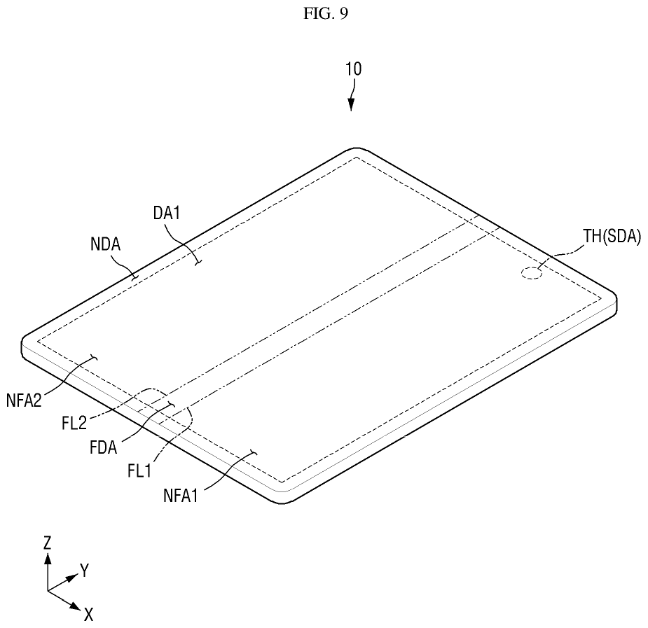

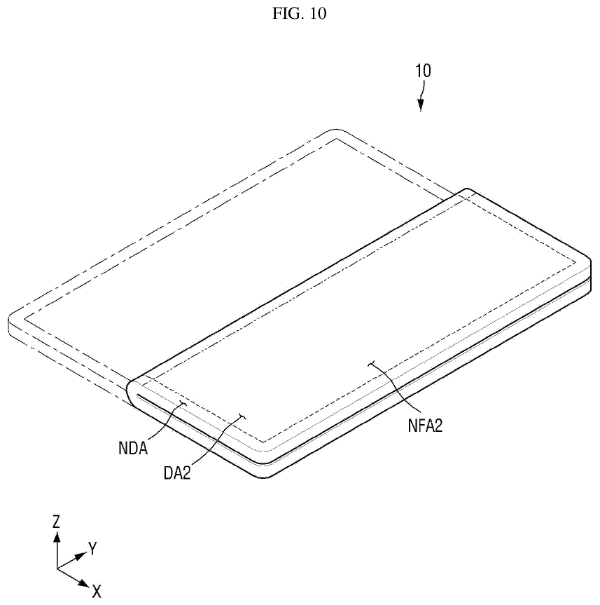

FIGS. 9 and 10 are perspective views of a display device according to another embodiment of the present disclosure.

In FIGS. 9 and 10, the display device 10 is illustrated as a foldable display device that is folded in the first direction (X-axis direction). The display device 10 may maintain both a folded state and an unfolded state. The display device 10 may be folded in an in-folding manner in which its front surface is disposed inside. When the display device 10 is bent or folded in the in-folding manner, portions of the front surface of the display device 10 may face each other. Alternatively, the display device 10 may be folded in an out-folding manner in which its front surface is disposed outside. When the display device 10 is bent or folded in the out-folding manner, portions of a rear surface of the display device 10 may face each other.

A first non-folding area NFA1 may be disposed on a side, e.g., a right side of a folding area FDA. A second non-folding area NFA2 may be disposed on the other side, e.g., a left side of the folding area FDA. A touch sensing unit TSU according to an embodiment of the present specification may be formed and disposed in each of the first non-folding area NFA1 and the second non-folding area NFA2.

A first folding line FL1 and a second folding line FL2 may extend in a second direction (Y-axis direction), and the display device 10 may be folded in the first direction (X-axis direction). Therefore, since a length of the display device 10 in the first direction (X-axis direction) can be reduced to about half, a user can easily carry the display device 10.

The direction in which the first folding line FL1 and the second folding line FL2 extend is not limited to the second direction (y-axis direction). For example, the first folding line FL1 and the second folding line FL2 may extend in the first direction (X-axis direction), and the display device 10 may be folded in the first direction the second direction (y-axis direction). In this case, a length of the display device 10 in the second direction (y-axis direction) may be reduced to about half. Alternatively, the first folding line FL1 and the second folding line FL2 may extend in a diagonal direction of the display device 10 between the first direction (X-axis direction) and the second direction (Y-axis direction). In this case, the display device 10 may be folded in a triangular shape.

When the first folding line FL1 and the second folding line FL2 are extended in the second direction (y-axis direction), the length of the folding area FDA in the first direction (x-axis direction) may be smaller than the length in the second direction (y-axis direction). In addition, the length of the first non-folding area NFA1 in the first direction (x-axis direction) may be larger than the length of the folding area FDA in the first direction (x-axis direction). The length of the second non-folding area NFA2 in the first direction (x-axis direction) may be larger than the length of the folding area FDA in the first direction (x-axis direction).

A first display area DA1 may be disposed on the front surface of the display device 10. The first display area DA1 may overlap the folding area FDA, the first non-folding area NFA1, and the second non-folding area NFA2. Therefore, when the display device 10 is unfolded, an image may be displayed in the forward direction on the folding area FDA, the first non-folding area NFA1, and the second non-folding area NFA2 of the display device 10.

A second display area DA2 may be disposed on the rear surface of the display device 10. The second display area DA2 may overlap the second non-folding area NFA2. Therefore, when the display device 10 is folded, an image may be displayed in the front direction in the second non-folding area NFA2 of the display device 10.

A through hole TH in which a camera SDA is formed is illustrated to be disposed in the first non-folding area NFA1 in FIGS. 9 and 10, but the present disclosure is not limited thereto. The through hole TH or the camera SDA may be disposed in the second non-folding area NFA2 or the folding area FDA.

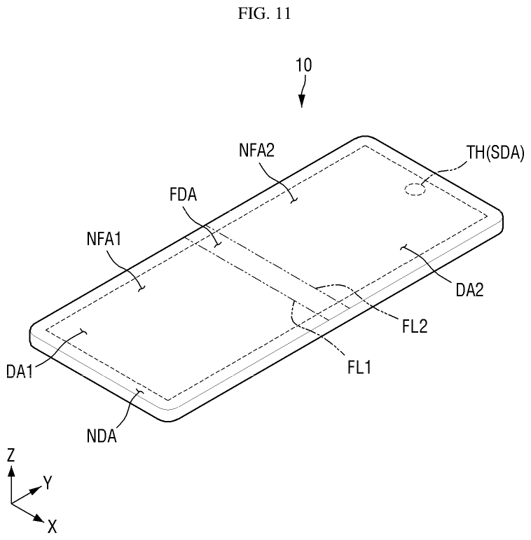

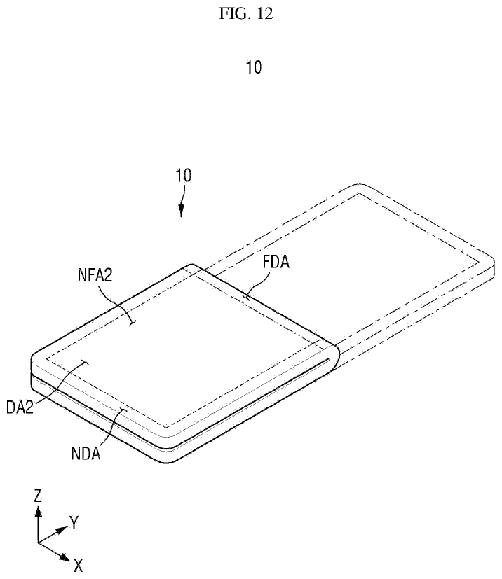

FIGS. 11 and 12 are perspective views of a display device 10 according to an embodiment of the present disclosure.

In FIGS. 11 and 12, the display device 10 is illustrated as a foldable display device that is folded in the second direction (Y-axis direction). The display device 10 may maintain both a folded state and an unfolded state. The display device 10 may be folded in an in-folding manner in which its front surface is disposed inside. When the display device 10 is bent or folded in the in-folding manner, portions of the front surface of the display device 10 may face each other. Alternatively, the display device 10 may be folded in an out-folding manner in which its front surface is disposed outside. When the display device 10 is bent or folded in the out-folding manner, portions of a rear surface of the display device 10 may face each other.

The display device 10 may include a folding area FDA, a first non-folding area NFA1, and a second non-folding area NFA2. The folding area FDA may be an area where the display device 10 is folded, and the first non-folding area NFA1 and the second non-folding area NFA2 may be areas where the display device 10 is not folded. The first non-folding area NFA1 may be disposed on a side, e.g., a lower side of the folding area FDA. The second non-folding area NFA2 may be disposed on the other side, e.g., an upper side of the folding area FDA.

The touch sensing unit TSU according to an embodiment of the present specification may be formed and disposed in each of the first non-folding area NFA1 and the second non-folding area NFA2.

On the other hand, the folding area FDA may be an area that is bent with a predetermined curvature along a first folding line FL1 and a second folding line FL2. Therefore, the first folding line FL1 may be a boundary between the folding area FDA and the first non-folding area NFA1, and the second folding line FL2 may be a boundary between the folding area FDA and the second non-folding area NFA2.

The first folding line FL1 and the second folding line FL2 may extend in the first direction (X-axis direction) as illustrated in FIGS. 11 and 12, and the display device 10 may be folded in the second direction (Y-axis direction). Therefore, since a length of the display device 10 in the second direction (Y-axis direction) can be reduced to about half, a user can easily carry the display device 10.

The first folding line FL1 and the second folding line FL2 may not necessarily extend in the first direction (X-axis direction). For example, the first folding line FL1 and the second folding line FL2 may extend in the second direction (Y-axis direction), and the display device 10 may be folded in the first direction (X-axis direction). In this case, a length of the display device 10 in the first direction (X-axis direction) may be reduced to about half. Alternatively, the first folding line FL1 and the second folding line FL2 may extend in a diagonal direction of the display device 10 between the first direction (X-axis direction) and the second direction (Y-axis direction). In this case, the display device 10 may be folded in a triangular shape.

When the first folding line FL1 and the second folding line FL2 extend in the first direction (X-axis direction) as illustrated in FIGS. 11 and 12, a length of the folding area FDA may be smaller in the second direction (Y-axis direction) than in the first direction (X-axis direction). In addition, a length of the first non-folding area NFA1 in the second direction (Y-axis direction) may be greater than the length of the folding area FDA in the second direction (Y-axis direction). A length of the second non-folding area NFA2 in the second direction (Y-axis direction) may be greater than the length of the folding area FDA in the second direction (Y-axis direction).

The first display area DA1 may be disposed on the front surface of the display device 10. The first display area DA1 may overlap the folding area FDA, the first non-folding area NFA1, and the second non-folding area NFA2. Therefore, when the display device 10 is unfolded, an image may be displayed in the forward direction on the folding area FDA, the first non-folding area NFA1, and the second non-folding area NFA2 of the display device 10.

The second display area DA2 may be disposed on the rear surface of the display device 10. The second display area DA2 may overlap the second non-folding area NFA2. Therefore, when the display device 10 is folded, an image may be displayed in the forward direction on the second non-folding area NFA2 of the display device 10.

Although a through hole TH in which a camera SDA or the like is placed is disposed in the second non-folding area NFA2 in FIGS. 11 and 12, the present disclosure is not limited thereto. The through hole TH may also be disposed in the first non-folding area NFA1 or the folding area FDA.

In concluding the detailed description, those skilled in the art will appreciate that many variations and modifications can be made to the preferred embodiments without substantially departing from the principles of the present disclosure. Therefore, the disclosed preferred embodiments of the disclosure are used in a generic and descriptive sense only and not for purposes of limitation.

What is claimed is:

1. A display device comprising:
a plurality of sub-pixels formed in a display area of a display panel;
a plurality of gate lines and a plurality of data lines electrically connected to the plurality of sub-pixels;
a plurality of fan-out lines formed in a non-display area of the display panel to be electrically connected to the plurality of data lines;
a plurality of gate control lines electrically connected to a gate driver formed in the non-display area; and
at least one line number identification pattern formed on at least one line among the plurality of gate lines, the plurality of data lines, the plurality of fan-out lines, and the plurality of gate control lines, wherein the line number identification pattern represents a line number for the at least one line.

2. The display device of claim 1,
wherein at least one line number identification pattern is formed on the one line as a wide portion that is wider than the at least one line, wherein there is a group formed of at least one wide portion on the at least one line to represent the line number.

3. The display device of claim 1,
wherein at least one line number identification pattern comprises a first identification pattern having either a square shape or a rectangular shape.

4. The display device of claim 3,
further comprising a second identification pattern having a rectangular shape formed on the one line.

5. The display device of claim 4,
wherein the at least one line number identification pattern comprises a plurality of first identification patterns spaced apart from each other, and the first identification pattern is spaced apart from the second identification pattern.

6. The display device of claim 4,
wherein a number of the first identification patterns on the at least one line represents a line number.

7. The display device of claim 4,
wherein the second identification pattern has a length or shape different from the first identification pattern so that the second identification pattern is recognized as predetermined number.

8. The display device of claim 4,
wherein at least one line has a first width,
wherein the first and second identification patterns are formed to have a second width greater than the first width, wherein an edge of at least one of the first and second identification patterns extends beyond an edge of the at least one line by a third width, and
wherein the third width is smaller than the first width.

9. The display device of claim 4,
wherein at least one line has a first width,
wherein the first and second identification patterns are formed to have a second width greater than the first width, wherein an edge of at least one of the first and second identification patterns extends beyond an edge of the at least one line by at least a third width along two sides of the at least one line, and
wherein the third width is smaller than the first width.

10. The display device of claim 4,
wherein the plurality of gate control lines and the at least one line number identification pattern formed on the at least one gate control line among the plurality of gate control lines are made of the same material on the same layer as a gate electrode through the same patterning process as the gate electrode of a thin film transistor included in a sub-pixel of the display area.

11. The display device of claim 10,
wherein the plurality of fan-out lines and at least one line number identification pattern formed on at least one fan-out line among the plurality of fan-out lines are made of the same material on the same layer as a gate electrode through the same patterning process as the gate electrode of a thin film transistor included in a sub-pixel of the display area.

12. The display device of claim 4,
wherein the plurality of fan-out lines and at least one line number identification pattern formed on at least one fan-out line among the plurality of fan-out lines are made of the same material on the same layer as source and drain electrodes through the same patterning process as the source and drain electrodes of a thin-film transistor included in a sub-pixel of the display area.

13. The display device of claim 12,
wherein the plurality of gate control lines and the at least one line number identification pattern formed on at least one gate control line among the plurality of gate control lines are made of the same material on the same layer as source and drain electrodes through the same patterning process as the source and drain electrodes of a thin-film transistor included in a sub-pixel of the display area.

14. A method of manufacturing a display device, the method comprising:
forming a barrier layer in a display area and a non-display area of a substrate;
forming a thin-film transistor on the barrier layer in the display area;
forming a plurality of gate lines and a plurality of data lines to be electrically connected to the thin-film transistor;
forming a plurality of fan-out lines in the non-display area to be electrically connected to the plurality of data lines; and
forming a plurality of gate control lines to be electrically connected to a gate driver formed in the non-display area,
wherein, in forming at least one line among the plurality of gate lines, the plurality of data lines, the plurality of fan-out lines and the plurality of gate control lines, at least one line number identification pattern is formed on the at least one line.

15. The method of claim 14, further comprising
forming the plurality of gate control lines and the at least one line number identification pattern on at least one gate control line among the plurality of gate control lines by using the same material on the same layer as a gate electrode through the same patterning process as the gate electrode of a thin-film transistor formed in the display area.

16. The method of claim 15, further comprising
forming the plurality of fan-out lines and the at least one line number identification pattern on at least one fan-out line among the plurality of fan-out lines by using the same material on the same layer as a gate electrode through the same patterning process as the gate electrode of a thin-film transistor formed in the display area.

17. The method of claim 14, further comprising
forming the plurality of fan-out lines and the at least one line number identification pattern on at least one fan-out line among the plurality of fan-out lines by using the same material on the same layer as source and drain electrodes through the same patterning process as the source and drain electrodes of a thin-film transistor formed in the display area.

18. The method of claim 17, further comprising
forming the plurality of gate control lines and the at least one line number identification pattern on at least one gate control line among the plurality of gate control lines by using the same material on the same layer as source and drain electrodes through the same patterning process as the source and drain electrodes of a thin film transistor formed in the display area.

19. The method of claim 14,
wherein the at least one line number identification pattern comprises:
a first identification pattern formed in a square shape or formed in a rectangular shape; and
a second identification pattern formed in a rectangular shape with sides that extend in the same direction as the at least one line being longer than the sides that extend perpendicularly to the at least one line.

20. The method of claim 19,
wherein a number of the first identification patterns on the at least one line represents a line number, and
wherein the second identification pattern has a length or shape different from the first identification pattern to represent a predetermined number.
